(19) United States
(12) Patent Application Publication
(10) Pub. No.: US 2025/0374618 A1
(43) Pub. Date: Dec. 4, 2025

(54) FORKSHEET STRUCTURE WITH FLEXIBLE CELL HEIGHT AND FLEXIBLE CHANNEL CONFIGURATION

(71) Applicant: International Business Machines Corporation, Armonk, NY (US)

(72) Inventors: Sagarika Mukesh, Albany, NY (US); Ruilong Xie, Niskayuna, NY (US); Tsung-Sheng Kang, Ballston Lake, NY (US); Tao Li, Slingerlands, NY (US)

(21) Appl. No.: 18/679,667

(22) Filed: May 31, 2024

(51) Int. Cl. H01L 29/06; H01L 27/088; H01L 29/423; H01L 29/66; H01L 29/775; H01L 29/786

(52) U.S. Cl. CPC H10D 62/116; H10D 30/014; H10D 30/43; H10D 30/6735; H10D 30/6757; H10D 62/121; H10D 84/83

(57) ABSTRACT

According to an embodiment of the present invention, a semiconductor device includes a substrate. A plurality of nanosheets are located parallel to the substrate. A silicon backbone extends upwards from the substrate through the plurality of nanosheets. The plurality of nanosheets extend laterally from lower sidewalls of the silicon backbone.

### BACKGROUND

The present invention relates generally to the field of microelectronics, and more particularly to a semiconductor device structure, and a method for forming a semiconductor device.

A nanosheet (NS) is the lead device architecture in continuing CMOS scaling. However, nanosheet technology has shown issues when scaling down such that as the devices become smaller and closer together, they are interfering with each other. Furthermore, as the devices become smaller and closer together, forming the connections to a backside power network is becoming more difficult.

### SUMMARY

According to an embodiment of the present invention, a semiconductor device includes a substrate. A plurality of nanosheets are located parallel to the substrate. A silicon backbone extends upwards from the substrate through the plurality of nanosheets. The plurality of nanosheets extend laterally from lower sidewalls of the silicon backbone.

According to an embodiment of the present invention, a semiconductor device includes a substrate. A plurality of nanosheets are located parallel to the substrate. A silicon backbone extends upwards from the substrate through the plurality of nanosheets. The plurality of nanosheets extend laterally from lower sidewalls of the silicon backbone. A first dielectric pillar extends downwards through the silicon backbone and a first portion of the substrate.

According to an embodiment of the present invention, a semiconductor device includes a substrate. A plurality of nanosheets are located parallel to the substrate. A silicon backbone extends upwards from the substrate through the plurality of nanosheets. The plurality of nanosheets extend laterally from lower sidewalls of the silicon backbone. A first dielectric pillar extends downwards through the silicon backbone and a first portion of the substrate. A shallow trench isolation (STI) region in direct contact with a frontside surface and a sidewall of the substrate. A second dielectric pillar extending downwards through a portion of the STI region.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 illustrates cross section X1 of the plurality of nanodevices after nanosheet formation and sacrificial layer formation, according to the embodiment of the present invention.

FIG. 2 illustrates cross section X1 of the plurality of nanodevices after gate hard mask formation and backbone patterning, according to the embodiment of the present invention.

FIG. 3 illustrates cross section X1 of the plurality of nanodevices after epitaxial growth and polish of silicon to fill trenches, according to the embodiment of the present invention.

FIG. 4 illustrates cross section X1 of the plurality of nanodevices after active area (RX) patterning, etching, and shallow trench isolation (STI), according to the embodiment of the present invention.

FIG. 5 illustrates cross section X2 of the plurality of nanodevices after source/drain (S/D) epitaxy formation, according to the embodiment of the present invention.

FIG. 6 illustrates cross section X1 of the plurality of nanodevices after gate formation and dielectric fin formation, according to the embodiment of the present invention.

FIGS. 7 and 8 illustrate cross sections X1 and X2, respectively, of the plurality of nanodevices after dielectric pillar 200, 202 formation, according to the embodiment of the present invention.

FIG. 9 illustrates cross section X1 of the plurality of nanodevices demonstrating the top dielectric fin helping prevent undercutting during multiple-Vt patterning, according to the embodiment of the present invention.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

References in the specification to “one embodiment,” “an embodiment,” “an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art to affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “formed on,” or “formed atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be a direct or indirect positional relationship. As an example of an indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both an indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes which are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout.

The traditional process for creating forksheet transistor structures involves creating ridges in a substrate and backfilling with a dielectric to create a backbone. Adequate epitaxy growth in these structures is crucial to ensure channel quality and structural integrity. However, this process may result in defective epitaxial growth, which may result in strain and dislocations, degraded performance, and reliability concerns.

By creating a backbone pattern in a modified nanosheet stack and then epitaxially growing silicon into the backbone cavities, a stronger backbone may be formed compared to a traditional dielectric backbone. Unlike a dielectric backbone that is prone to epitaxy defects, a silicon backbone may grow defect-free or with only minor defects in the device region. The present invention does not require that all advantages need to be incorporated into every embodiment of the invention.

The present invention is directed to forming a forksheet transistor structure with flexible cell height and flexible channel configuration to enable optimal epitaxial growth. The forksheet structure is formed through a multistage processing, where the first stage forms a modified nanosheet stack. The second stage forms two or more first trenches in the modified nanosheet stack through backbone patterning. The third stage epitaxially grows silicon to fill the two or more first trenches generated through the backbone patterning. The fourth stage forms a forksheet structure through active region (RX) patterning and etching. The fifth stage forms source/drains on the modified nanosheet stack. The sixth stage forms gates through high-k metal gate (HKMG) formation. The seventh stage forms two or more second trenches by etching through the backbone pattern or between the backbones. The eighth stage fills the two or more second trenches with a dielectric material to form the dielectric pillars.

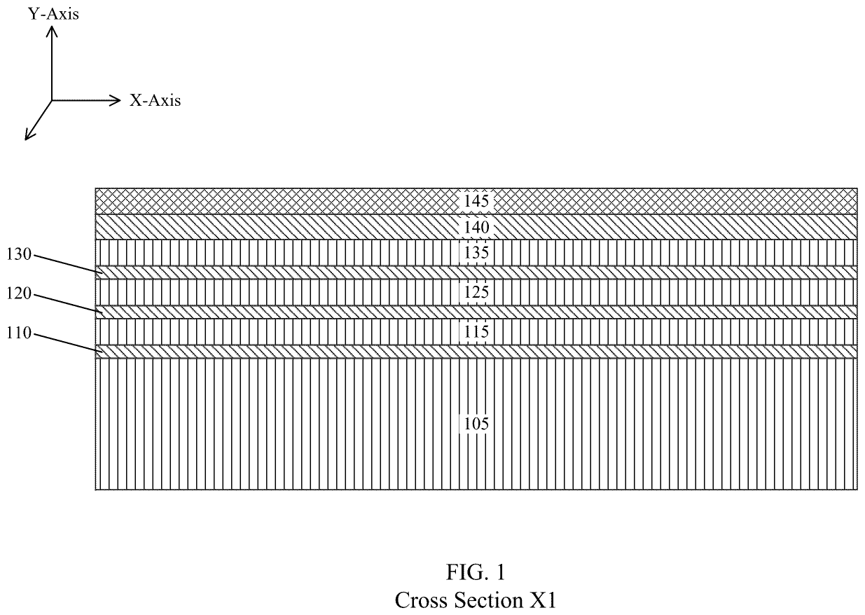

FIG. 1 illustrates cross section X1 of the plurality of nanodevices after nanosheet 115, 125, 135 formation and sacrificial layer 110, 120, 130, 140, 145 formation according to the embodiment of the present invention. The modified nanosheet stack may include various layers of semiconductor materials, such as a substrate 105, the plurality of nanosheets 115, 125, 135, and the plurality of sacrificial layers 110, 120, 130, 140, 145. The substrate 105, the plurality of nanosheets 115, 125, 135, and the plurality of sacrificial layers 110, 120, 130, 140, 145 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of the semiconductor materials can be used as the semiconductor material of the substrate 105. In the embodiment, the substrate 105 includes both semiconductor materials and dielectric materials. The semiconductor substrate 105 may also comprise an organic semiconductor or a layered semiconductor such as, for example, Si/SiGe, a silicon-on-insulator or a SiGe-on-insulator. A portion or the entire substrate 105 may also be comprised of an amorphous, polycrystalline, or monocrystalline. The substrate 105 may be doped, undoped or contain doped regions and undoped regions therein. For example, the substrate 105, the first nanosheet 115, the second nanosheet 125, and the third nanosheet 135 may be comprised of silicon, whereas the first sacrificial layer 110, the second sacrificial layer 120, the third sacrificial layer 130, and the fourth sacrificial 140 may be comprises of SiGe, where Ge is about 25%, and the fifth sacrificial layer 145 may be comprised of SiGe, where Ge is about 55%.

The first sacrificial layer 110 is formed directly atop the substrate 105. The first nanosheet 115 is formed directly atop the first sacrificial layer 110. The second sacrificial layer 120 is formed directly atop the first nanosheet 115. The second nanosheet 125 is formed directly atop the second sacrificial layer 120. The third sacrificial layer 130 is formed directly atop the second nanosheet 125. The third nanosheet 135 is formed directly atop the third sacrificial layer 130. The fourth sacrificial layer 140 is formed directly atop the third nanosheet 135. The fifth sacrificial layer 145 is formed directly atop the fourth sacrificial layer 140. The number of layers described above are not intended to be limiting, and it may be appreciated that in the embodiment of the present invention the number of layers may vary.

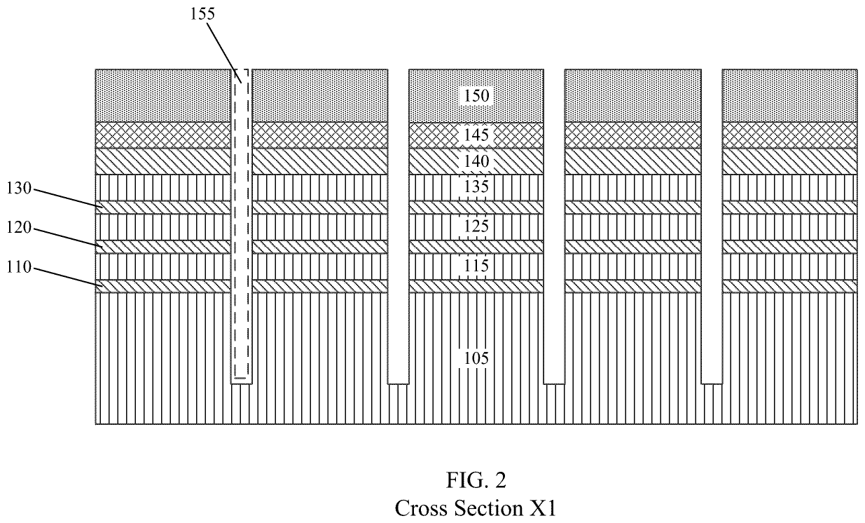

FIG. 2 illustrates cross section X1 of the plurality of nanodevices after gate hard mask 150 formation and backbone patterning, according to the embodiment of the present invention. In FIG. 2, a gate hard mask 150 is formed directly atop the underlying fifth sacrificial layer 145. The gate hard mask 150 may be a film that is more resistant to etching than conventional photoresist. Then, a portion of the substrate 105, the plurality of nanosheets 115, 125, 135, the plurality of sacrificial layers 110, 120, 130, 140, 145, and gate hard mask 150 are etched to form a plurality of trenches 155.

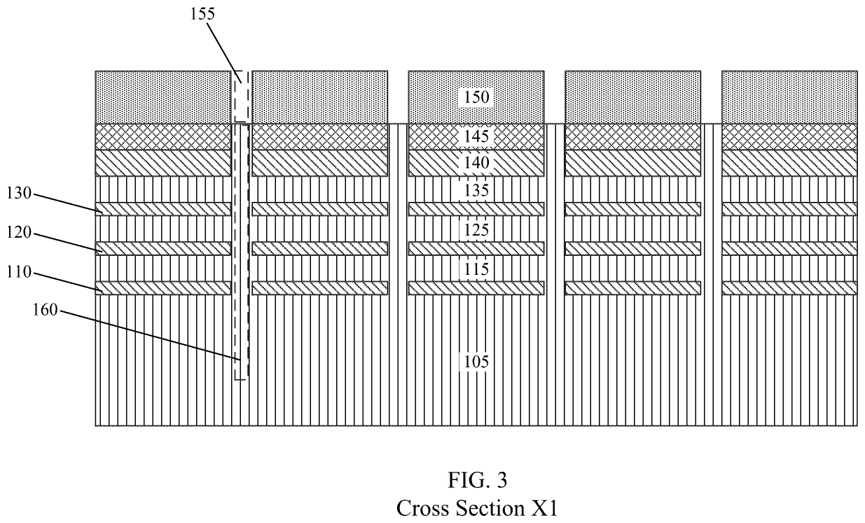

FIG. 3 illustrates cross section X1 of the plurality of nanodevices after epitaxial growth and polish of silicon to fill the plurality of trenches 155, according to the embodiment of the present invention. In FIG. 3, silicon is epitaxially grown and polished in the plurality of trenches 155 to create a plurality of backbones 160 to the top of the fifth sacrificial layer 145. The plurality of backbones have a width W1. As such, the substrate 105, the first nanosheet 115, the second nanosheet 125, the third nanosheet 135, and the plurality of backbones form a unitary structure.

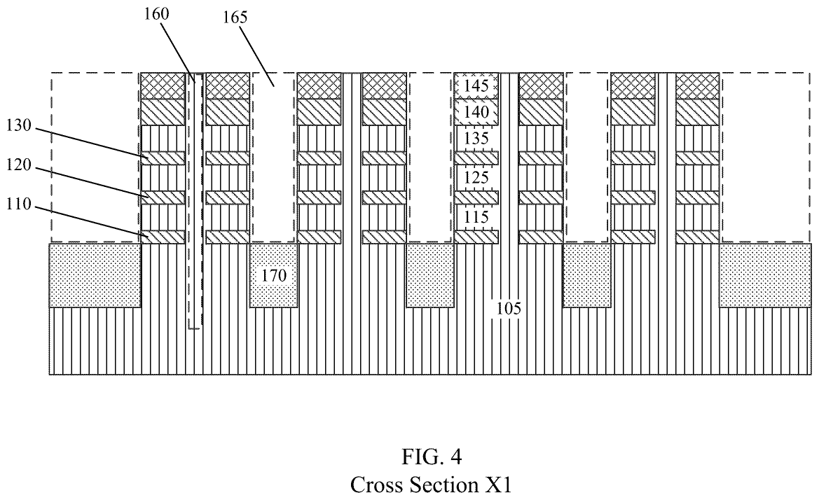

FIG. 4 illustrates cross section X1 of the plurality of nanodevices after active region (RX) patterning, etching, and shallow trench isolation (STI) region 170 formation, according to the embodiment of the present invention. In FIG. 4, the gate hard mask 150 is removed and a portion of the plurality of nanosheets 115, 125, 135, the plurality of sacrificial layers 110, 120, 130, 140, 145, and the substrate 105 are etched to form a second plurality of trenches 165 between the plurality of backbones 160.

The STI region 170 is then formed within the second plurality of trenches so that the STI region 170 is flush with the bottom of the first sacrificial layer 110. The STI region 170 relates to a structure that separates neighboring transistors or memory cells. The STI region 170 is formed by etching a shallow trench (not shown) and then filling that trench with an insulating material.

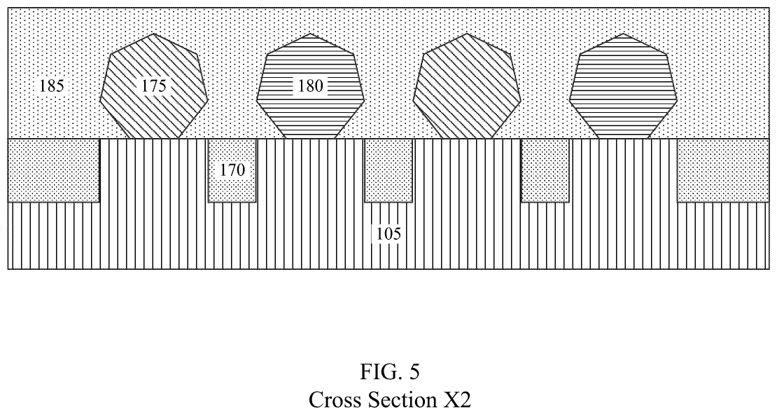

FIG. 5 illustrates cross section X2 of the plurality of nanodevices after source/drain 175, 180 formation, according to the embodiment of the present invention. Once RX patterning and etching are performed, source/drains 175, 180 are formed. The source/drains 175, 180 are epitaxially grown over exposed sidewalls of the plurality of nanosheets 110, 120, 130 (FIG. 4). Due to formation of the plurality of backbones 160 using silicon, less defective epitaxial growth is observed. Following the formation of the source/drains 175, 180, an interlayer dielectric (ILD) 185 is formed around the source/drains 175, 180. The ILD 185 is an insulating material that provides electrical isolation between conducting layers. The ILD 185 is formed directly atop the STI region 170, the substrate 105, and the source/drains 175, 180. In the embodiment, the first source/drain 175 is an n-FET and the second source/drain 180 is a p-FET. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (TI) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

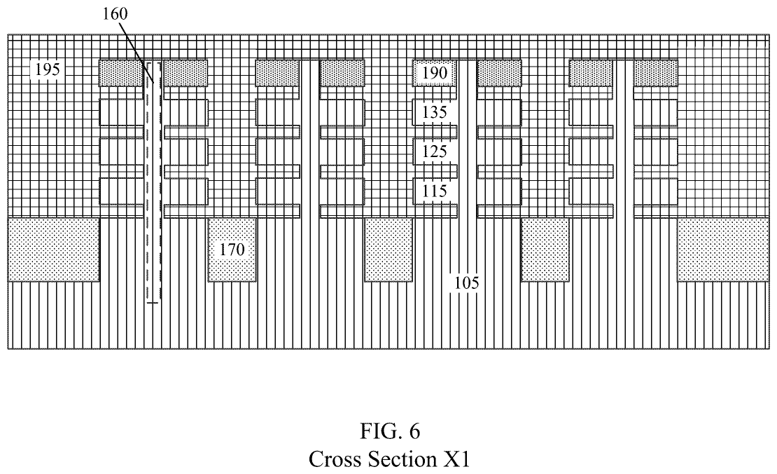

FIG. 6 illustrates cross section X1 of the plurality of nanodevices after a first gate 195 formation and dielectric fin 190 formation, according to the embodiment of the present invention. A gate material is deposited in the space created by the removal of the plurality of sacrificial layers 115, 125, 135, in the second plurality of trenches 165, and directly atop the plurality of dielectric fins 190 to form a replacement gate (i.e., the first gate 195). The first gate 195 can be comprised of, for example, a gate dielectric liner, such as a high-k dielectric like HfO2, ZrO2, HfLaOx, etc., and work function layers, such as TiN, TiAlC, TiC, etc., and conductive metal fills, like W. During first gate 195 formation, the fifth sacrificial layer 145 is selectively removed and replaced with a plurality of dielectric fins 190 during gate spacer (not shown) deposition. The plurality of dielectric fins 190 are formed on upper sidewalls of the plurality of backbones 160. The dielectric used in the plurality of dielectric fins 190 is any non-conductive material used to insulate conductive components in a device.

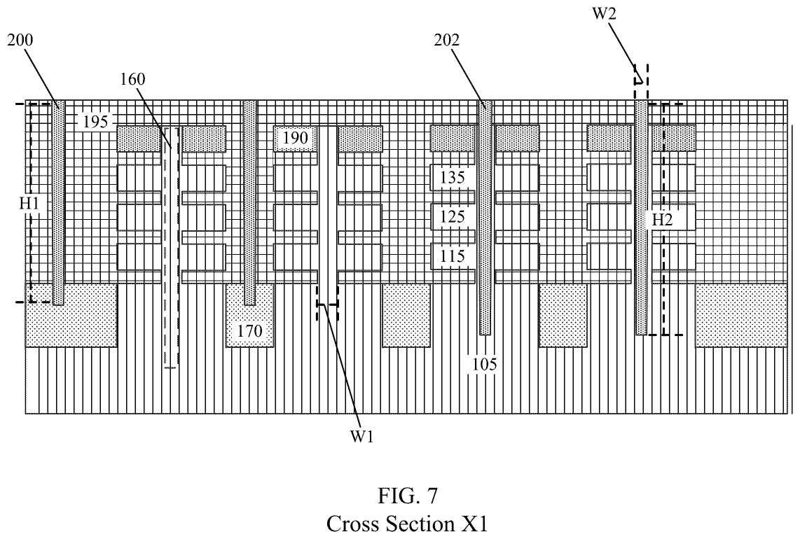

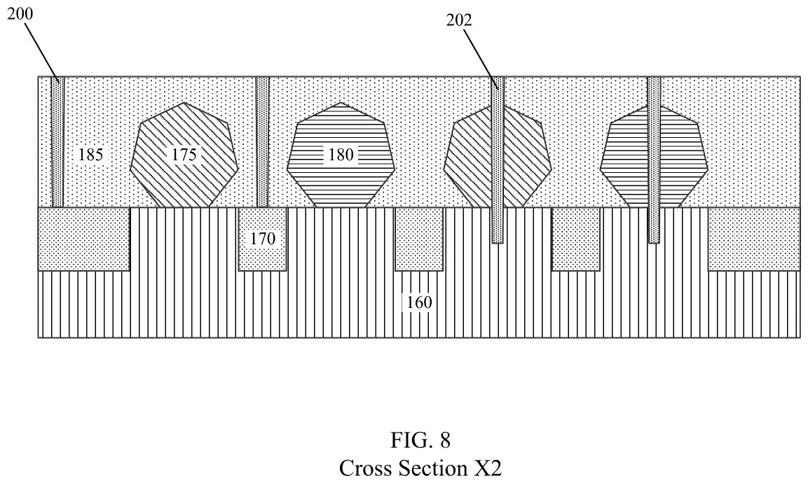

FIGS. 7 and 8 illustrate cross sections X1 and X2, respectively, of the plurality of nanodevices after dielectric pillar 200, 202 formation, according to the embodiment of the present invention. In FIG. 7, a third plurality of trenches (not shown) formed during middle-of-line (MOL) patterning are filled with a dielectric material to form the first dielectric pillars 200 (i.e., the second dielectric pillar in the claims) and the second dielectric pillars 202 (i.e., the first dielectric pillar in the claims). The first dielectric pillars 200 extend a first height H1 perpendicular to a y-axis. The second dielectric pillars 202 extended a second height H2 perpendicular to the y-axis. The second height H2 is greater than the first height H1. Additionally, the second dielectric pillars 202 have a width W2. The width W1 of the plurality of backbones 160 is greater than the width W2 of the second dielectric pillars 202. The dielectric material may be comprised of, for example, SiN, SiBCN, SiOCN, SiOC, or SiC.. In FIG. 7, the first dielectric pillars 200 extend downwards through the first gate 195 and a portion of the STI region 170. The second dielectric pillars 202 extend downwards through a portion of the first gate 195, a backbone in the plurality of backbones 160, and a portion of the substrate 105. In FIG. 8, the first dielectric pillars 200 extend downwards through the ILD 185. A bottom surface of the first dielectric pillar 200 is in direct contact with the STI region 170. The second dielectric pillars 202 extend downwards through the source/drains 175, 180 and a portion of the substrate 105.

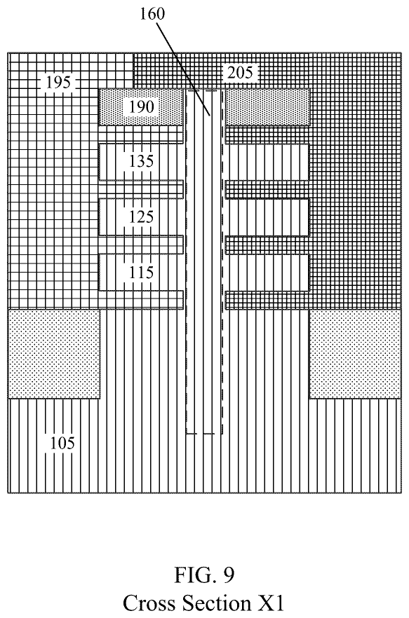

FIG. 9 illustrates cross section X1 of the plurality of nanodevices demonstrating the top dielectric fins 190 helping prevent undercutting during multiple-Vt patterning, according to the embodiment of the present invention. In FIG. 9, multiple-Vt patterning allows for an n-FET on one side of the backbone 160 and a p-FET to be placed on the other side of the backbone 160. Depending on the patterning on the side of the backbone, the first gate 195 is formed or the second gate 205 is formed. The second gate 205 can be comprised of, for example, a gate dielectric liner, such as a high-k dielectric like HfO2, ZrO2, HfLaOx, etc., and work function layers, such as TiN, TiAlC, TiC, etc., and conductive metal fills, like W. The second gate is a different material than the first gate 195 but formed in the same manner as the first gate 195, described above. Use of a silicon backbone 160 enables multiple Vt-patterning where the top dielectric fins 190 prevent undercutting.

It may be appreciated that FIGS. 1-9 provide only an illustration of one implementation and do not imply any limitations with regard to how different embodiments may be implemented. Many modifications to the depicted environments may be made based on design and implementation requirements.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a substrate;
a plurality of nanosheets located parallel to the substrate; and
a silicon backbone extending upwards from the substrate through the plurality of nanosheets, wherein the plurality of nanosheets extend laterally from lower sidewalls of the silicon backbone.

2. The semiconductor device of claim 1, wherein the substrate, the plurality of nanosheets, and the silicon backbone are comprised of silicon.

3. The semiconductor device of claim 1, wherein the substrate, the plurality of nanosheets, and the silicon backbone are joined in a forksheet structure.

4. The semiconductor device of claim 1, further comprising:
a plurality of dielectric fins on upper sidewalls of the silicon backbone.

5. The semiconductor device of claim 1, further comprising:
a source/drain in direct contact with a frontside surface of the substrate.

6. The semiconductor device of claim 5, further comprising:
an interlayer dielectric (ILD) in direct contact to exposed sidewalls of the plurality of nanosheets, a frontside surface of the source/drain, and a sidewall of the plurality of nanosheets.

7. The semiconductor device of claim 4, further comprising:
a gate between the plurality of nanosheets and in direct contact with a frontside surface and exposed sidewalls of the plurality of dielectric fins.

8. A semiconductor device comprising:
a substrate;
a plurality of nanosheets located parallel to the substrate;
a silicon backbone extending upwards from the substrate through the plurality of nanosheets, wherein the plurality of nanosheets extend laterally from lower sidewalls of the silicon backbone; and
a first dielectric pillar extending downwards through the silicon backbone and a portion of the substrate.

9. The semiconductor device of claim 8, wherein the substrate, the plurality of nanosheets, and the silicon backbone are comprised of silicon.

10. The semiconductor device of claim 8, wherein the substrate, the plurality of nanosheets, and the silicon backbone are joined in a forksheet structure.

11. The semiconductor device of claim 8, further comprising:
a plurality of dielectric fins on upper sidewalls of the silicon backbone.

12. The semiconductor device of claim 8, further comprising:
a source/drain in direct contact with a frontside surface of the substrate.

13. The semiconductor device of claim 12, further comprising:
an interlayer dielectric (ILD) in direct contact to exposed sidewalls of the plurality of nanosheets, a frontside surface of the source/drain, and a sidewall of the plurality of nanosheets.

14. The semiconductor device of claim 11, further comprising:
a gate between the plurality of nanosheets and in direct contact to a frontside surface and exposed sidewalls of the plurality of dielectric fins.

15. A semiconductor device comprising:
a substrate;
a plurality of nanosheets located parallel to the substrate;
a silicon backbone extending upwards from the substrate through the plurality of nanosheets, wherein the plurality of nanosheets extend laterally from lower sidewalls of the silicon backbone;
a first dielectric pillar extending downwards through the silicon backbone and a first portion of the substrate;
a shallow trench isolation (STI) region in direct contact with a frontside surface and a sidewall of the substrate; and
a second dielectric pillar extending downwards through a portion of the STI region.

16. The semiconductor device of claim 1, wherein the substrate, the plurality of nanosheets, and the silicon backbone are comprised of silicon.

17. The semiconductor device of claim 15, wherein the substrate, the plurality of nanosheets, and the silicon backbone are joined in a forksheet structure.

18. The semiconductor device of claim 15, further comprising:
a plurality of dielectric fins on upper sidewalls of the silicon backbone.

19. The semiconductor device of claim 15, further comprising:
a source/drain in direct contact with a frontside surface of the substrate.

20. The semiconductor device of claim 19, further comprising:
an interlayer dielectric (ILD) in direct contact to exposed sidewalls of the plurality of nanosheets, a frontside surface of the source/drain, and a sidewall of the plurality of nanosheets.
